(19) United States
(12) Patent Application Publication
(10) Pub. No.: US 2024/0139699 A1
(43) Pub. Date: May 2, 2024

(54) APPARATUS FOR PROCESSING CHEMICAL LIQUID

(71) Applicant: SEMES CO., LTD., Cheonan-si (KR)

(72) Inventors: Donghwa Lee, Cheonan-si (KR); Daigeon Yoon, Cheonan-si (KR); Bongman Choi, Cheonan-si (KR); Soohong Lee, Cheonan-si (KR); Daesung Kim, Cheonan-si (KR)

(21) Appl. No.: 18/375,177

(22) Filed: Sep. 29, 2023

(30) Foreign Application Priority Data
Oct. 31, 2022 (KR) 10-2022-0142465

(51) Int. Cl. B01J 8/08

(52) U.S. Cl. CPC B01J 8/085; B01J 8/082

(57) ABSTRACT

The disclosure provides a chemical liquid supply apparatus including a chemical liquid storage tank storing a chemical liquid including a plurality of nanorods, a circulation pipe having both ends connected to the chemical liquid storage tank and including a first branch pipe and a second branch pipe, a classifier located at the second branch pipe and including a classification chip and a power supply, and a discharge pipe configured to discharge the chemical liquid to an outside of the circulation pipe, wherein the classification chip collects and releases nanorods of a certain size among the plurality of nanorods, the discharge pipe discharges the nanorods of the certain size to the outside before the nanorods of the certain size released by the classification chip are returned to the chemical liquid storage tank, and the power supply supplies an alternating current to the classification chip.

### CROSS-REFERENCE TO RELATED APPLICATION

This application is based on and claims priority under 35 U.S.C. § 119 to Korean Patent Application No. 10-2022-0142465, filed on Oct. 31, 2022, in the Korean Intellectual Property Office, the disclosure of which is incorporated by reference herein in its entirety.

### BACKGROUND

### 1. Field

The disclosure relates to a chemical liquid supply apparatus, and more particularly, to a chemical liquid supply apparatus that may classify nanorods included in a chemical liquid.

### 2. Description of the Related Art

With further development in displays using quantum dot (QD) materials and organic light-emitting diodes (OLEDs), interest in quantum nano emitting diode (QNED) (or QD-inorganic LED) displays is increasing. QNEDs are the same as OLEDs in that quantum dot materials are used for color conversion, but QNEDs use inorganic LEDs, not OLEDs, as light-emitting devices that emit light incident on a quantum dot material, and particularly, a main feature of QNEDs is that inorganic LEDs are used in the form of nanorods which are dipoles. The nanorods used in QNEDs are nano-sized materials like nanoparticles but are named nanorods due to their high aspect ratio, which is a ratio of diameter to height, and because the nanorods used for QNEDs are manufactured in heights ranging from hundreds of nanometers to micrometers, sizes of nanorods have to be uniform compared to a quantum dot material dispersed in ink to which inkjet printing is applied.

### SUMMARY

The disclosure provides a chemical liquid supply apparatus that may collect nanorods of a certain size and apply uniform nanorods on a substrate.

The disclosure provides a chemical liquid supply apparatus that may be used without replacing a foreign matter filter by releasing the collected nanorods.

In addition, objects to be achieved by the disclosure is not limited to the objects described above, and other objects may be clearly understood by those skilled in the art from the description below.

Additional aspects will be set forth in part in the description which follows and, in part, will be apparent from the description, or may be learned by practice of the presented embodiments of the disclosure.

According to an aspect of the disclosure, a chemical liquid supply apparatus includes a chemical liquid storage tank storing a chemical liquid including a plurality of nanorods, a circulation pipe having both ends connected to the chemical liquid storage tank and including a first branch pipe and a second branch pipe, a classifier located at the second branch pipe and including a classification chip and a power supply, and a discharge pipe configured to discharge the chemical liquid to an outside of the circulation pipe, wherein the classification chip collects and releases nanorods of a certain size among the plurality of nanorods, the discharge pipe discharges the nanorods of the certain size to the outside before the nanorods of the certain size released by the classification chip are returned to the chemical liquid storage tank, and the power supply supplies an alternating current to the classification chip.

According to another aspect of the disclosure, a chemical liquid supply apparatus includes a chemical liquid storage tank storing a chemical liquid including a plurality of nanorods, a circulation pipe having both ends connected to the chemical liquid storage tank and including a main flow pipe and a plurality of branch pipes, a plurality of classifiers located at the plurality of branch pipes and each including a classification chip and a power supply, a plurality of discharge pipes configured to discharge the chemical liquid to an outside of the circulation pipe, and a plurality of control valves respectively located at the plurality of branch pipes and respectively adjusting flow rates of the chemical liquid flowing through the plurality of branch pipes, wherein the classification chip collects and releases nanorods of a certain size among the plurality of nanorods, the plurality of discharge pipes discharge the nanorods of the certain size to the outside before the nanorods of the certain size released by the classification chip are returned to the chemical liquid storage tank, and the power supply supplies an alternating current to the classification chip.

According to another aspect of the disclosure, a chemical liquid supply apparatus includes a chemical liquid storage tank storing a chemical liquid including a plurality of nanorods, a circulation pipe having both ends connected to the chemical liquid storage tank and including a main flow pipe and a plurality of branch pipes, a degassing device located at the circulation pipe and configured to remove air bubbles in the chemical liquid, a distribution measurer located at the chemical liquid storage tank and configured to measure a degree of distribution of the plurality of nanorods in the chemical liquid, a plurality of classifiers respectively located at the plurality of branch pipes and each including a classification chip and a power supply, a plurality of discharge pipes configured to discharge the chemical liquid to an outside of the circulation pipe, a plurality of control valves respectively located at the plurality of branch pipes and configured to adjust flow rates of the chemical liquid flowing through the plurality of branch pipes, a head configured to spray the chemical liquid onto a substrate, a supply pipe and a return pipe connecting the head and the chemical liquid storage tank to each other, and a controller configured to control collection and release of the nanorods of the classifier, wherein the classification chip includes a first electrode layer, an insulting layer, and a second electrode layer and collects and releases nanorods of a certain size among the plurality of nanorods, the plurality of discharge pipes discharge the nanorods of the certain size to the outside before the nanorods of the certain size released by the classification chip are returned to the chemical liquid storage tank, the power supply supplies an alternating current to the classification chip, and the controller controls the plurality of classifiers to collect the nanorods of the certain size while the head is spraying the chemical liquid and controls the plurality of classifiers to release the nanorods through the plurality of discharge pipes while the head is not spraying the chemical liquid.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A to 1B are schematic configuration diagrams of a chemical liquid supply apparatus according to an embodiment of the disclosure;

FIG. 2 is a schematic plan view of a classification chip of the chemical liquid supply apparatus of FIG. 1A;

FIGS. 3 and 4 are schematic diagrams illustrating an operation process of a classifier of a chemical liquid supply apparatus according to an embodiment of the disclosure;

FIG. 5 is a schematic configuration diagram of a classifier of a chemical liquid supply apparatus according to an embodiment of the disclosure;

FIG. 6 is a schematic configuration diagram of a chemical liquid supply apparatus according to an embodiment of the disclosure;

FIG. 7 is a schematic configuration diagram of a chemical liquid supply apparatus according to an embodiment of the disclosure; and

FIGS. 8 to 10 are schematic configuration diagrams of chemical liquid supply apparatuses according to embodiments of the disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The present embodiments may have various changes and various forms, and accordingly, some embodiments will be illustrated in the drawings and described in detail. However, this is not intended to limit the present embodiments to a specific disclosure.

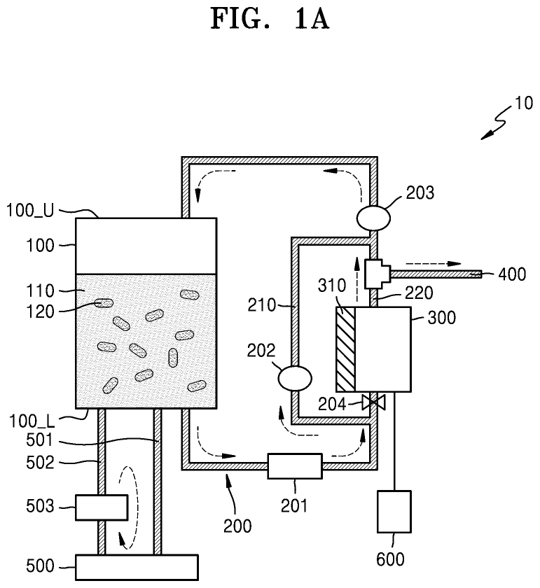

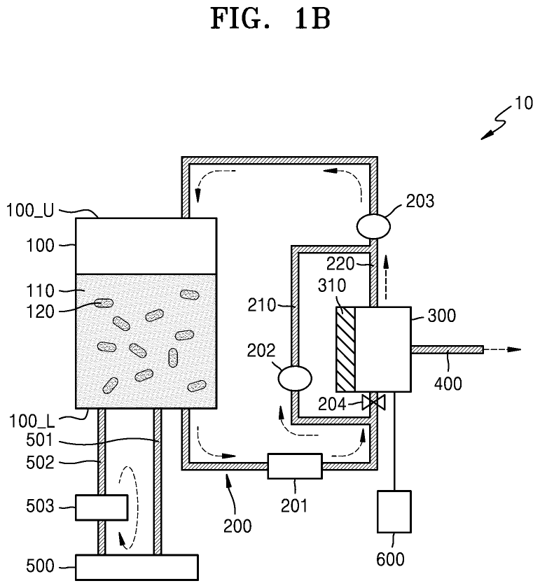

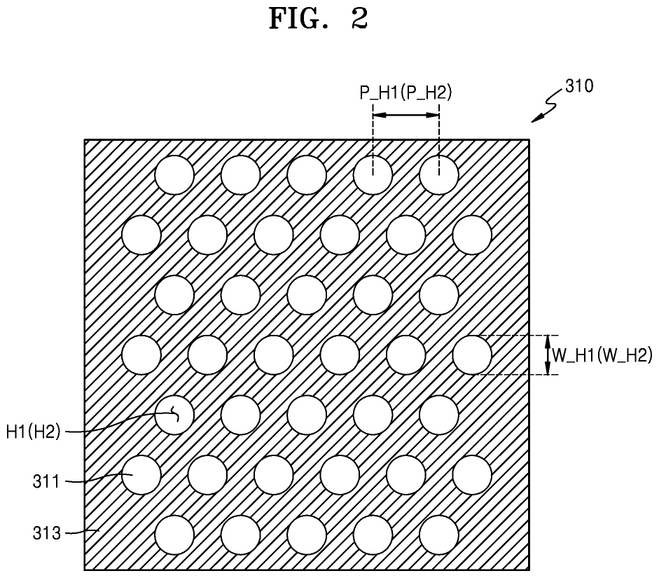

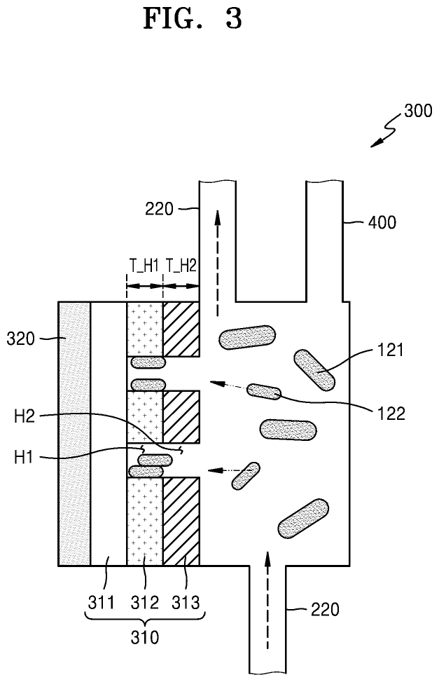

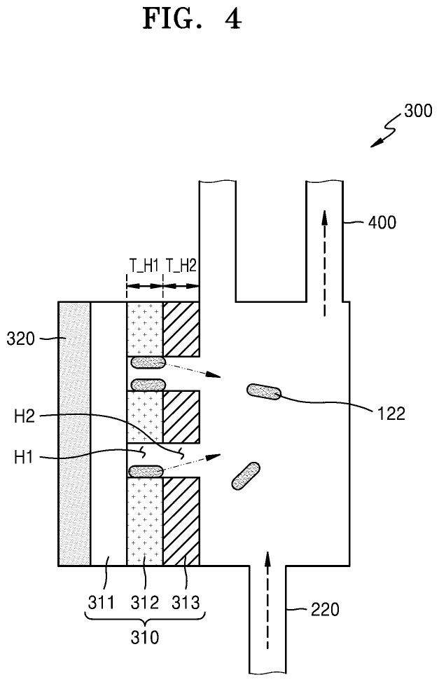

FIGS. 1A to 1B are schematic configuration diagrams of a chemical liquid supply apparatus according to an embodiment of the disclosure. FIG. 2 is a schematic plan view of a classification chip of the chemical liquid supply apparatus illustrated in FIG. 1A. FIGS. 3 and 4 are schematic diagrams illustrating an operation process of a classifier of a chemical liquid supply apparatus according to an embodiment of the disclosure.

Referring to FIGS. 1A to 4, a chemical liquid supply apparatus 10 may include a chemical liquid storage tank 100, a circulation pipe 200, a classifier 300, a discharge pipe 400, a head 500, and a controller 600.

The chemical liquid storage tank 100 of the chemical liquid supply apparatus 10 may store a chemical liquid 110 including nanorods 120. The chemical liquid storage tank 100 may include an upper surface 100_U and a lower surface 100_L. The chemical liquid 110 may include a plurality of nanorods 120. The nanorods 120 included in the chemical liquid 110 may each have a shape with a high aspect ratio of diameter to height. The nanorods 120 are dipole materials and may be aligned by an electric field. That is, positions of the nanorods 120 may be moved by dielectrophoresis (DEP) or direction of the nanorods 120 may be aligned by the DEP.

Both ends of the circulation pipe 200 of the chemical liquid supply apparatus 10 may be connected to the chemical liquid storage tank 100. That is, both ends of the circulation pipe 200 may be connected to the liquid chemical liquid storage tank 100 such that the chemical liquid 110 stored in the liquid chemical liquid storage tank 100 may be circulated. In other words, the chemical liquid 110 flowing from the chemical liquid storage tank 100 to the circulation pipe 200 may return to the chemical liquid storage tank 100 by passing through the circulation pipe 200. In some embodiments, one end of the circulation pipe 200 may be connected to the lower surface 100_L of the liquid chemical liquid storage tank, and the other end may be connected to the upper surface 100_U of the chemical liquid storage tank 100. In other words, the chemical liquid 110 may flow out of one end of the circulation pipe 200 connected to the lower surface 100_L of the chemical liquid storage tank 100 and flow into the other end of the circulation pipe 200 connected to the upper surface 100_U of the chemical liquid storage tank 100. That is, both ends of the circulation pipe 200 may be connected to positions of different heights of the chemical liquid storage tank 100.

The circulation pipe 200 may include a first branch pipe 210, a second branch pipe 220, a circulation pipe pump 201, a first flow rate measurer 202, and a second flow rate measurer 203.

The circulation pipe 200 may branch into the first branch pipe 210 and the second branch pipe 220 from one pipe. Specifically, after the circulation pipe 200 branches into the first branch pipe 210 and the second branch pipe 220 from one pipe, the first branch pipe 210 and the second branch pipe 220 may combine with each other to form one pipe.

The circulation pipe pump 201 of the circulation pipe 200 may provide power to the circulation pipe 200 such that the chemical liquid 110 flows through the circulation pipe 200. In some embodiments, the circulation pipe pump 201 may adjust the amount of liquids flowing through the circulation pipe 200. In some embodiments, the circulation pipe pump 201 may include any one of a centrifugal pump, a side flow pump, a reciprocating pump, a magnetic levitation pump, and a rotary pump.

The first flow rate measurer 202 of the circulation pipe 200 may measure a flow rate of a liquid flowing into the first branch pipe 210. The second flow rate measurer 203 of the circulation pipe 200 may measure a flow rate of a liquid flowing into the circulation pipe 200. A flow rate of a liquid flowing through the second branch pipe 220 may be calculated by using a value measured by the first flow rate measurer 202 and a value measured by the second flow rate measurer 203. In some embodiments, the flow rate of the liquid flowing through the second branch pipe 220 may be less than the flow rate of the liquid flowing through the first branch pipe 210. In some embodiments, the second flow rate measurer 203 may be located at the circulation pipe 200 behind a combined position of the first branch pipe 210 and the second branch pipe 220.

A control valve 204 of the circulation pipe 200 may adjust a flow rate of the chemical liquid 110 flowing into the second branch pipe 220. The flow rate of the chemical liquid 110 flowing into the second branch pipe 220 may be less than a flow rate of the chemical liquid 110 flowing into the first branch pipe 210. That is, the control valve 204 may control a flow rate of a chemical liquid flowing into the branch pipe at which the classifier 300 is located to be less than a flow rate of the chemical liquid flowing into the other branch pipe. Although an example in which the control valve 204 is at the second branch pipe 220 is illustrated in FIG. 1A, the control valve 204 is not limited thereto and may be located at the first branch pipe 210 to adjust a flow rate of the chemical liquid 110 flowing into the first branch pipe 210.

The plurality of nanorods 120 of the chemical liquid 110 may be deposited on the lower surface 100_L of the chemical liquid storage tank by gravity. The circulation pipe 200 according to the disclosure discharges the chemical liquid 110 from the lower surface 100_L) of the chemical liquid storage tank 100, introduces the chemical liquid 110 into the upper surface 100_U of the chemical liquid storage tank 100, and accordingly, it is possible to prevent the nanorods 120 from being deposited on the lower surface 100_L of the chemical liquid storage tank 100.

The classifier 300 of the chemical liquid supply apparatus 10 may be located at the second branch pipe 220. In other words, the classifier 300 may be located at the branch pipe with a less flow rate among the first branch pipe 210 and the second branch pipe 220. The classifier 300 may include a classification chip 310 in FIG. 3 and a power supply 320 in FIG. 3.

The classification chip 310 of the classifier 300 may collect and release nanorods 122 of a certain size from among the plurality of nanorods 120. In some embodiments, the classification chip 310 may separate only the nanorods 122 of a certain size from among the plurality of nanorods 120 included in the chemical liquid 110 flowing through the second branch pipe 220.

The classification chip 310 may include a first electrode layer 311, an insulating layer 312, and a second electrode layer 313. The insulating layer 312 may be between the first electrode layer 311 and the second electrode layer 313. That is, the first electrode layer 311, the insulating layer 312, and the second electrode layer 313 may be sequentially stacked. In some embodiments, the first electrode layer 311 and the second electrode layer 313 may receive power from the power supply 320. An electric field may be formed between the first electrode layer 311 and the second electrode layer 313.

The insulating layer 312 of the classification chip 310 may have a first hole H1. The second electrode layer 313 of the classification chip 310 may have a second hole H2. The second hole H2 may communicate with the first hole H1. In other words, the second electrode layer 313 may have the second hole H2 having the same size as the first hole H1. The first hole H1 may extend to a lower surface of the insulting layer 312 by passing through an upper surface of the insulating layer 312, and the second hole H2 may extend to a lower surface of the second electrode layer 313 by passing through an upper surface of the second electrode layer 313. That is, when the classification chip 310 is viewed from the top, the first electrode layer 311 may be exposed to the outside by the first hole H1 and the second hole H2. Although FIG. 2 illustrates as an example that the first hole H1 and the second hole H2 each have a circular shape, the first hole H1 and the second hole H2 are not limited thereto and may each have a polygonal shape, such as a quadrangular shape, a pentagonal shape, or a hexagonal shape.

In some embodiments, a thickness T_H1 of the first hole H1 may be about 5 μm to about 600 μm, and a thickness T_H2 of the second hole H2 may be about 5 μm to about 600 μm. That is, the sum of the thickness of the first hole T_H1 and the thickness of the second hole T_H2 may be about 10 μm to about 1200 μm.

In some embodiments, a width W_H1 of the first hole H1 may be about 10 μm to about 800 μm. A width W_H2 of the second hole H2 may be about 10 μm to about 800 μm. In some embodiments, the width W_H1 of the first hole H1 and the width W_H2 of the second hole H2 may be the same. That is, a sidewall forming the width W_H1 of the first hole H1 and a sidewall forming the width W_H2 of the second hole H2 may form a common surface.

In some embodiments, the insulating layer 312 may have a plurality of first holes H1, and the second electrode layer 313 may have a plurality of second holes H2. The plurality of second holes H2 may respectively communicate with the plurality of first holes H1. In some embodiments, the plurality of first holes H1 may be separated from each other by a first distance P_H1. The plurality of second holes H2 may be separated from each other by a second distance P_H2. The first distance P_H1 and the second distance P_H2 may be about 10 μm to about 100 μm. In some embodiments, the first distance P_H1 may be equal to the second distance P_H2.

An electric field may be formed by the first electrode layer 311 and the second electrode layer 313 of the classification chip 310. The plurality of nanorods 120 included in the chemical liquid 110 flowing through the classifier 300 may receive a dielectrophoretic force by an electric field. The dielectrophoretic force may vary depending on frequencies of the electric field. That is, when conditions under which DEP is formed are the same, the nanorods 122 of a certain size may be separated. In other words, the nanorods 122 of a certain size may be collected and released by the electric field formed by the first electrode layer 311 and the second electrode layer 313. Accordingly, the plurality of nanorods 120 may be classified into the nanorods 122 of a certain size and nanorods 121 of the other sizes. The nanorods 122 of a certain size separated by the DEP may be accommodated in the first hole H1 and the second hole H2. That is, the nanorods 122 of a certain size classified by an electric field may be collected in the first hole H1 and the second hole H2 formed in the classification chip 310.

The power supply 320 of the classifier 300 may supply power to the first electrode layer 311 and the second electrode layer 313 of the classification chip 310. A current supplied by the power supply 320 to the first electrode layer 311 and the second electrode layer 313 may include an alternating current. In some embodiments, a frequency of the alternating current may be between about 1 MHz and about 1000 MHz. The frequency of the alternating current of the power supply 320 may vary depending on sizes of the nanorods to be collected and released. That is, sizes of the nanorods to be collected and released may be adjusted by adjusting the frequency of the power supply 320.

The plurality of nanorods 120 included in the chemical liquid 110 may have sizes substantially different from each other. A high-quality display may be obtained only by spraying nanorods of a uniform size when arranging the nanorods on a substrate. The classifier 300 according to the disclosure may collect the nanorods 122 of a certain size among the plurality of nanorods 120 of different sizes, and accordingly, the chemical liquid 110 passing through the classifier 300 may only include nanorods of size within a tolerance range. In other words, the quality of a display formed of the chemical liquid 110 supplied by the chemical liquid supply apparatus 10 may be improved by collecting nanorods of a size outside an error range by using the classifier.

The discharge pipe 400 of the chemical liquid supply apparatus 10 may discharge the chemical liquid 110 to the outside of the circulation pipe 200. That is, the chemical liquid supply apparatus 10 may discharge at least a part of the chemical liquid 110 to the outside of the circulation pipe 200 through the discharge pipe 400. In some embodiments, the chemical liquid 110 flowing into the classifier 300 may be discharged to the outside of the circulation pipe 200. In some embodiments, the nanorods 122 of a certain size collected by the classification chip 310 may be released through the discharge pipe 400. That is, the discharge pipe 400 may discharge the nanorods 122 of a certain size released from the classification chip 310 to the outside. The chemical liquid 110 discharged from the discharge pipe 400 may be discharged to the outside to be discarded or may be sent to a separate storage tank.

The discharge pipe 400 may discharge the nanorods 122 of a certain size to the outside before the nanorods 122 of a certain size released by the classification chip 310 are returned to the chemical liquid storage tank 100. In some embodiments, the discharge pipe 400 may be located at the second branch pipe 220 through which the chemical liquid 110 passing through the classification chip 310 flows. In some embodiments, the discharge pipe 400 may be connected to the classifier 300. Although FIGS. 1A and 1B illustrate that the discharge pipe 400 is connected to the second branch pipe 220 or the classifier 300, the discharge pipe 400 is not limited thereto and may be connected to the circulation pipe 200 behind the second branch pipe 220.

The nanorods 122 of a certain size collected by the classification chip 310 are released through the release pipe 400, and accordingly, the classifier 300 may be continuously used without replacing the classification chip 310. Therefore, the classifier 300 is connected to the discharge pipe 400 to periodically releases the collected nanorods 122 of a certain size, and accordingly, the classifier 300 may be used without replacement unlike a foreign matter filter.

The head 500 of the chemical liquid supply apparatus 10 may spray the chemical liquid 110 onto the substrate. That is, the chemical liquid 110 stored in the chemical liquid storage tank 100 may be sprayed onto the substrate through the head 500. A supply pipe 501 and a return pipe 502 of the chemical liquid supply apparatus 10 may connect the chemical liquid storage tank 100 to the head 500. Specifically, the supply pipe 501 may provide a passage for the chemical liquid 110 to move from the chemical liquid storage tank 100 to the head 500, and the return pipe 502 may provide a passage through which the mechanical liquid 110 remaining in the head 500 moves to the chemical liquid storage tank 100. A head pump 503 of the chemical liquid supply apparatus 10 may provide power to circulate the chemical liquid 110 between the chemical liquid storage tank 100 and the head 500. In some embodiments, the head pump 503 may be located at the return pipe 502. The head pump 503 may include at least one of a centrifugal pump, a side flow pump, a reciprocating pump, a magnetic levitation pump, and a rotary pump.

The controller 600 of the chemical liquid supply apparatus 10 may control collection and release of the nanorods 120 of the classifier 300. That is, the controller 600 may control the classifier 300 to collect the nanorods 122 of a certain size or to release the nanorods 122 of a certain size. In some embodiments, while the chemical liquid 110 is supplied to the head 500 and is sprayed onto a substrate, the controller 600 may control the classifier 300 to collect the nanorods 122 of a certain size. While the chemical liquid 110 is not sprayed onto the substrate, the controller 600 may control the nanorods 122 of a certain size collected in the classifier 300 to be released. In other words, the controller 600 may control the classifier 300 to collect the nanorods 122 of a certain size while the chemical liquid supply apparatus 10 performs printing on the substrate. The controller 600 may control the chemical liquid supply apparatus 10 to release the collected nanorods 122 of a certain size when the substrate is not being printed. A substrate printing process is a process in which the head 500 sprays the chemical liquid 110 onto the substrate, and a substrate non-printing process is a process in which the head 500 does not spray the chemical liquid 110 onto the substrate.

Referring to FIGS. 3 and 4, FIG. 3 illustrates a state of the classifier 300 when the controller 600 controls the classifier 300 to collect the nanorods 122 of a certain size, and FIG. 4 illustrates a state of the classifier 300 when the controller 600 controls the classifier 300 to release the nanorods 122 of a certain size collected in the classifier 300.

While the chemical liquid supply apparatus 10 performs printing on a substrate, the controller 600 may control the classifier 300 not to discharge a chemical liquid to the discharge pipe 400. In some embodiments, the controller 600 may block a passage connected to the discharge pipe 400 while printing of the substrate such that the chemical liquid 110 does not flow out of the circulation pipe 200 from the classifier 300. In addition, during the printing of the substrate, the controller 600 may cause power to be supplied from the power supply 320 to the classification chip 310 to form an electric field, and accordingly, the nanorods 122 of a certain size may be collected in the first hole H1 and the second hole H1. In other words, the controller 600 may cause the nanorods 122 of a certain size included in the chemical liquid 110 flowed into the classifier 300 to be collected during the printing of the substrate and may case the other nanorods 121 to flow out to the second branch pipe 220.

The controller 600 may control the classifier 300 to discharge the chemical liquid to the discharge pipe 400 while the chemical liquid supply apparatus 10 does not perform printing on a substrate. In some embodiments, the controller 600 may open a passage connected to the discharge pipe 400 during non-printing of the substrate, such that the chemical liquid 110 flows from the classifier 300 to the outside of the circulation pipe 200. In addition, the controller 600 may adjust the frequency of the power supply 320 during the non-printing of the substrate, such that the collected nanorods 122 of a certain size are released from the first hole H1 and the second hole H2. In other words, the controller 600 may release the nanorods 122 of a certain size collected during printing of the substrate to the outside of the circulation pipe 200 through the discharge pipe 400 during the non-printing.

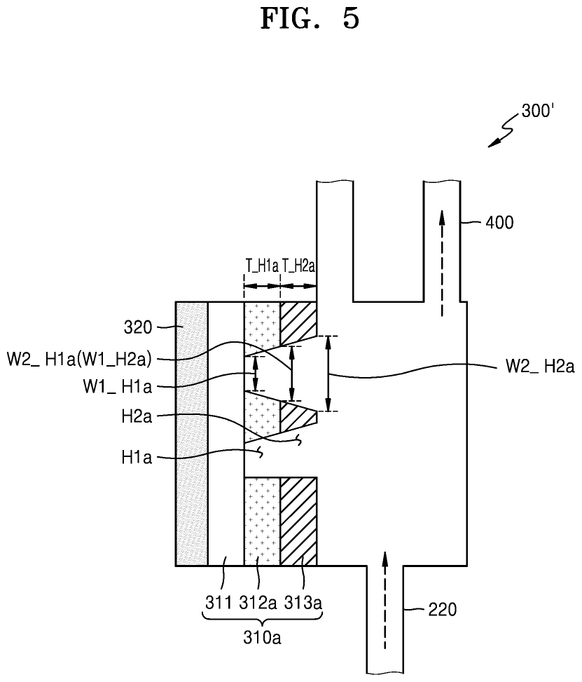

FIG. 5 is a schematic configuration diagram illustrating a classifier of a chemical liquid supply apparatus according to an embodiment of the disclosure.

Hereinafter, overlapping contents of a classifier in FIG. 5 and the classifier in FIG. 3 are omitted, and differences therebetween are described.

Referring to FIG. 5, the chemical liquid supply apparatus 10 may include a classifier 300′. The classifier 300′ may include a classification chip 310a and the power supply 320. The classification chip 310a may include the first electrode layer 311, an insulating layer 312a, and a second electrode layer 313a. The insulating layer 312a may have a first hole H1a, and the second electrode layer 313a may have a second hole H2a communicating with the first hole H1a.

A width of the first hole H1a may be reduced as the first hole H1a approaches the first electrode layer 311. That is, the first hole H1a may have a tapered shape in which the width is reduced as the first hole H1a approaches the first electrode layer 311. In other words, a sidewall forming the first hole H1a may be inclined to be reduced as the first hole H1a approaches the first electrode layer 311. In some embodiments, the first hole H1a may have a first width W1_H1a on a lower surface of the insulating layer 312a and may have a second width W2_H1a on an upper surface of the insulating layer 312a. The first width W1_H1a may be less than the second width W2_H1a.

A width of the second hole H2 may be reduced as the second hole H2 approaches the insulating layer 312a. That is, the second hole H2a may have a tapered shape in which the width is reduced as the second hole H2a approaches the insulating layer 312a. In other words, a sidewall forming the second hole H2a may be inclined to be less as the second hole H2a approaches the insulating layer 312a. In some embodiments, the second hole H2a may have a third width W1_H2a on a lower surface of the second electrode layer 313a and may have a fourth width W2_H2a on an upper surface of the second electrode layer 313a. The third width W1_H2a may be less than the fourth width W2_H2a. In some embodiments, the third width W1_H2a may be equal to the second width W2_H1a of the first hole H1. That is, the first hole H1a may communicate with the second hole H2a, and an upper surface of the first hole H1a may have the same area as a lower surface of the second hole H2a.

The classification chip 310a according to the disclosure may include the first hole H1a and the second hole H2a, each having a tapered shape. The first hole H1a and the second hole H2a each have an upper surface having a larger area to easily collect the nanorods 122 (in FIG. 3) of a certain size and each have a lower surface having a less area to prevent the collected nanorods 122 from being unintentionally released.

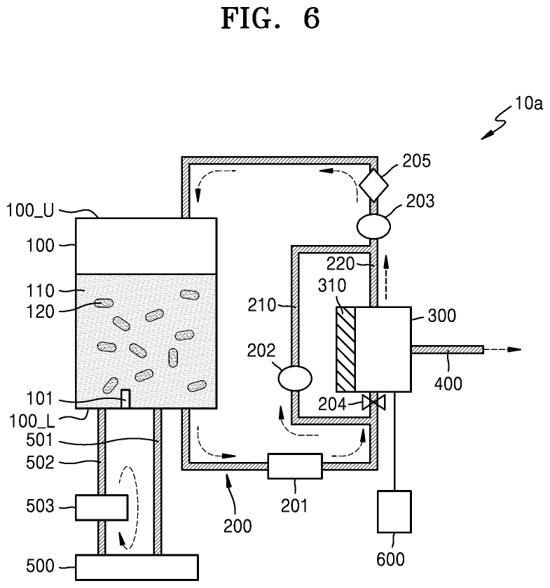

FIG. 6 is a schematic configuration diagram of a chemical liquid supply apparatus according to an embodiment of the disclosure.

Hereinafter, overlapping contents of a chemical liquid supply apparatus 10a in FIG. 6 and the chemical liquid supply apparatus 10 in FIG. 1A are omitted and differences therebetween are described.

Referring to FIG. 6, the chemical liquid supply apparatus 10a may further include a degassing device 205 and a distribution measurer 101.

The degassing device 205 of the chemical liquid supply apparatus 10a may be located at the circulation pipe 200. The degassing device 205 may remove air bubbles in the chemical liquid 110. In some embodiments, air bubbles may be formed inside the chemical liquid 110 while a chemical liquid is distributed to the first branch pipe 210 and the second branch pipe 220 from the circulation pipe 200 and is combined from the first branch pipe 210 and the second branch pipe 220 to the circulation pipe 200. The air bubbles in the chemical liquid 110 may degrade the quality of a display during printing of a substrate. The chemical liquid supply apparatus 10a according to the disclosure may removes the air bubbles present in the chemical liquid 110 by using the degassing device 205, and thus, the quality of the display may be improved.

The distribution measurer 101 of the chemical liquid supply apparatus 10a may measure a degree of distribution of the plurality of nanorods 120 in the chemical liquid 110. That is, the number of the plurality of nanorods 120 in the chemical liquid 110 may be measured. In other words, the number of the plurality of nanorods 120 per certain volume of the chemical liquid 110 may be measured. The distribution measurer 101 may be inside the chemical liquid storage tank 100. When a certain amount of nanorods are sprayed onto a substrate, a display may emit uniform brightness in all areas. The chemical liquid supply apparatus 10a according to the disclosure may measure the degree of distribution of the plurality of nanorods 120 in the chemical liquid by using the distribution measurer 101 and print a high-quality display.

Although the chemical liquid supply apparatus 10a including the degassing device 205 and the distribution measurer 101 is illustrated in FIG. 6, the chemical liquid supply device 10a is not limited thereto and may include either the degassing device 205 or the distribution measurer 101.

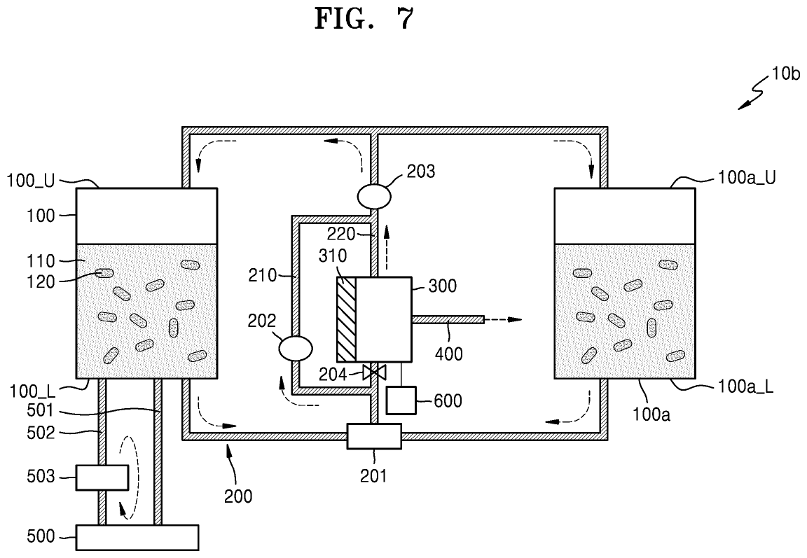

FIG. 7 is a schematic configuration diagram of a chemical liquid supply apparatus according to an embodiment of the disclosure.

Hereinafter, overlapping contents of a chemical liquid supply apparatus 10b in FIG. 7 and the chemical liquid supply apparatus 10 in FIG. 1A are omitted and differences therebetween are described.

Referring to FIG. 7, the chemical liquid supply apparatus 10b may include a plurality of chemical liquid storage tanks. In some embodiments, the liquid chemical supply apparatus 10b may include a first chemical liquid storage tank 100 and a second chemical liquid storage tank 100a. The first liquid chemical liquid storage tank 100 and the second chemical liquid storage tank 100a may each store a chemical liquid 110 including a plurality of nanorods 120. A circulation pipe 200 may be connected to the first chemical liquid storage tank 100 and the second chemical liquid storage tank 100a. That is, the circulation pipe 200 may provide a passage through which the chemical liquid 110 flows out from a lower surface 100_L of the first chemical liquid storage tank 100 and a lower surface 100a_L of the second chemical liquid storage tank 100a and flows into an upper surface 100_U of the first chemical liquid storage tank 100 and an upper surface 100a_U of the second chemical liquid storage tank 100a. Although FIG. 7 illustrates an example in which the first chemical liquid storage tank 100 is connected to a head 500, the disclosure is not limited thereto, and the first chemical liquid storage tank 100 and the second chemical liquid storage tank 100a may be connected to the head 500.

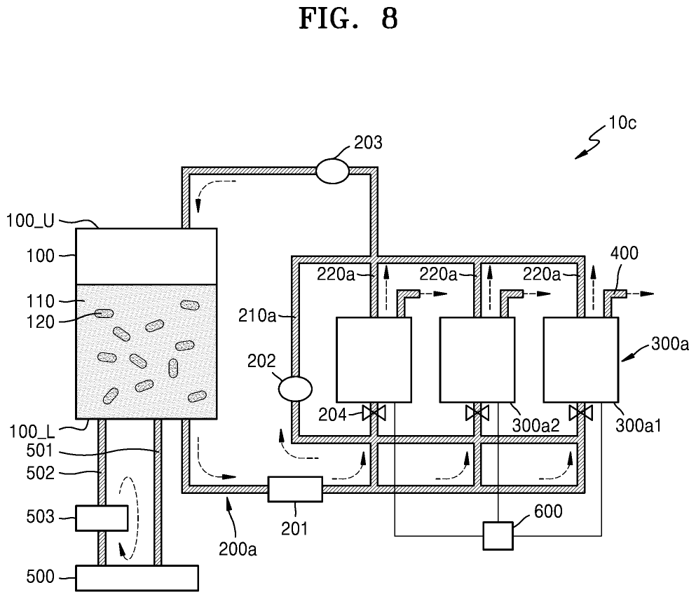

FIGS. 8 to 10 are schematic configuration diagrams of chemical liquid supply apparatuses according to embodiments of the disclosure.

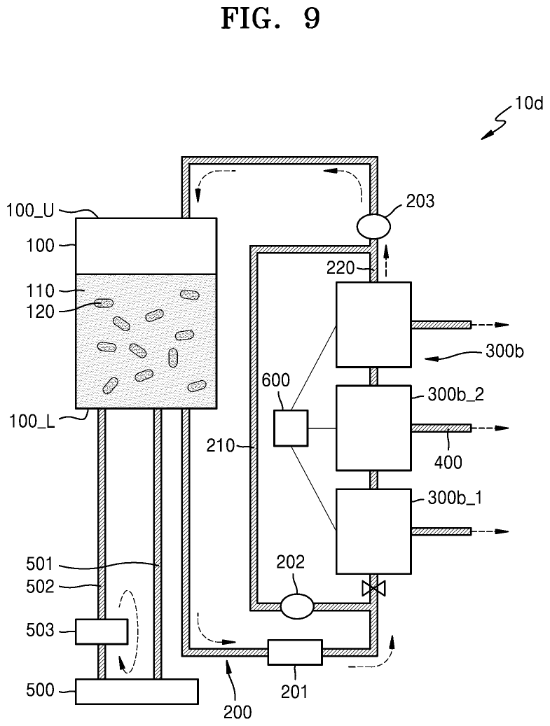

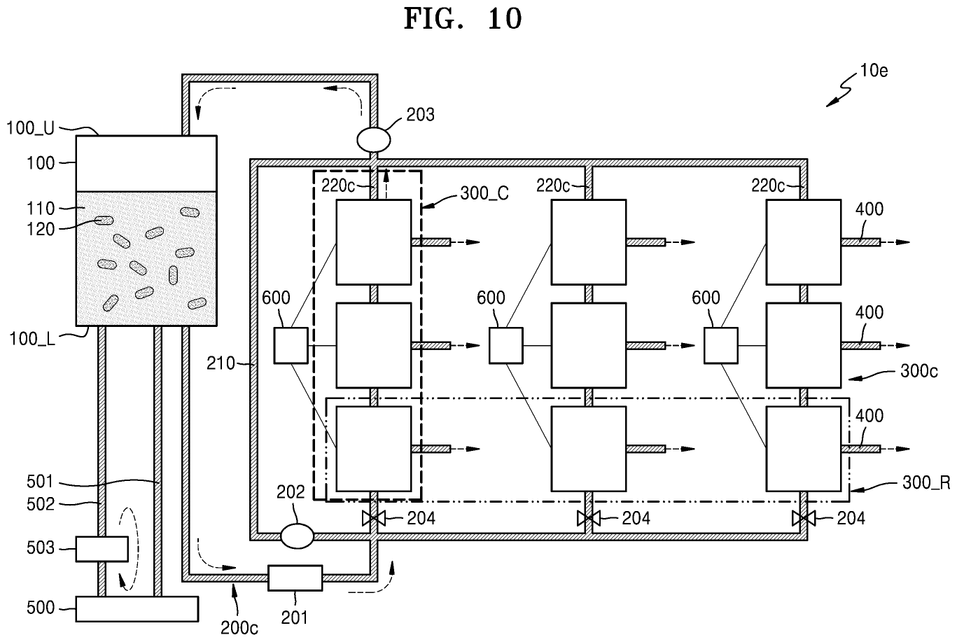

Hereinafter, overlapping contents of chemical liquid supply apparatuses 10c, 10d, and 10e respectively illustrated in FIG. 8, FIG. 9, and FIG. 10 and the chemical liquid supply apparatus 10 in FIG. 1A are omitted and differences therebetween are described.

Referring to FIG. 8, a circulation pipe 200a of the chemical liquid supply apparatus 10c may include a main flow pipe 210a and a plurality of branch pipes 220a. In other words, the circulation pipe 200a may have both ends connected to the chemical liquid storage tank 100 and may include the main flow pipe 210a and the plurality of branch pipes 220a branching into a plurality of branches between both ends of the circulation pipe 200. Flow rate of chemical liquids that may be accommodated in the plurality of branch pipes 220a may be less than a flow rate of a chemical liquid that may be accommodated in the main flow pipe 210a.

The plurality of branch pipes 220a of the chemical liquid supply apparatus 10c may respectively include control valves 204. That is, chemical liquids flowing through the plurality of branch pipes 220a may have different flow rates. The control valves 204 may respectively control flow rates of the chemical liquids to the most appropriate flow rates at which nanorods of a certain size may be classified in each of a plurality of classifiers 300a.

The plurality of classifiers 300a of the chemical liquid supply apparatus 10c may be respectively located at the plurality of branch pipes 220a. In other words, the branch pipes and the classifiers may correspond one-to-one. The plurality of classifiers 300a may respectively include classification chips and power supplies. The classification chips of the plurality of classifiers 300a respectively installed in the plurality of branch pipes 220a may collect and release nanorods of a certain size from the plurality of branch pipes. In some embodiments, the plurality of classifiers 300a may include the classifier 300 illustrated in FIG. 1A or the classifier 300′ illustrated in FIG. 5.

In some embodiments, the plurality of classifiers 300a of the chemical liquid supply apparatus 10c may be in parallel to a plurality of different branch pipes 220a. In some embodiments, the plurality of classifiers 300a in parallel to the plurality of different branch pipes 220a may collect and release nanorods of the same size. That is, the plurality of classifiers 300a configured to collect and release the nanorods of the same size may be respectively located at the plurality of branch pipes 220a that are different from each other. In other words, the plurality of classifiers 300a that may collect the nanorods of the same size may be installed in each of the plurality of branch pipes 220a. Specifically, a first classifier 300a1 may be located at one of the plurality of branch pipes 220a. A second classifier 300a2 may be located at a branch pipe different from the branch pipe. The first classifier 300a1 and the second classifier 300a2 may collect and release nanorods of the same size.

One classifier may classify nanorods of a certain size in a chemical liquid of a low flow rate. In the circulation pipe 200a according to the disclosure, the plurality of classifiers 300a that may collect nanorods of the same size may be located at each of the plurality of branch pipes 220a. Accordingly, the chemical liquid supply apparatus 10c may classify nanorods of a certain size at a high flow rate. Accordingly, the chemical liquid supply apparatus 10c according to the disclosure may efficiently classify the nanorods of a certain size.

In some embodiments, a plurality of classifiers 300b of the chemical liquid supply apparatus 10d may be located in series at one branch pipe among the plurality of branch pipes. In other words, in one branch pipe, a chemical liquid passing through one classifier may flow into another classifier. In some embodiments, the plurality of classifiers 300b located in series may collect and release nanorods of different sizes. In other words, a plurality of classifiers 300b configured to collect and release nanorods of different sizes may be located at one branch pipe. In other words, the plurality of classifiers 300b that may collect nanorods of different sizes may be installed in one branch pipe among the plurality of branch pipes. Specifically, a third classifier 300b1 and a fourth classifier 300b2 may be located at one branch pipe. The third classifier 300b1 and the fourth classifier 300b2 may collect and release nanorods of different sizes.

The plurality of classifiers 300b may each collect and release nanorods of a certain set size. The classifiers may adjust sizes of the nanorods to be collected and released by controlling DEP, such as frequency. By installing a plurality of classifiers that may collect nanorods of different sizes at one branch pipe, nanorods of various sizes may be collected and released in one cycle. The chemical liquid supply apparatus 10d according to the disclosure may classify nanorods other than the nanorods mounted on a display among the plurality of nanorods at once through the plurality of classifiers 300b arranged in series. Therefore, it is possible to prevent nanorods outside an error range from being sprayed onto a substrate, and thus, a high-quality display may be obtained.

In some embodiments, a plurality of classifiers 300c of the chemical liquid supply apparatus 10e include a first group 300_R in which sizes of nanorods to be collected and released are the same as each other, and a second group 300_C in which the sizes of the nanorods are different from each other. The first group 300_R may be located at a plurality of different branch pipes, and the second group 300_C may be located at one branch pipe. That is, a plurality of classifiers that collect nanorods of the same size may be located in parallel at a plurality of different branch pipes. The classifiers that collect nanorods of different sizes may be located in series at one branch pipe.

In some embodiments, the plurality of classifiers 300c may include first to third classifiers. The first classifier and the second classifier may collect nanorods of the same size, and the first classifier and the third classifier may collect nanorods of different sizes. That is, the first classifier and the second classifier may form the first group 300_R, and the first classifier and the third classifier may form the second group 300_C. The first classifier and the second classifier may be located at a plurality of different branch pipes, and the first classifier and the third classifier may be located at the same branch pipe.

One classifier may classify nanorods of a certain size at a low flow rate. In a circulation pipe 200c according to the disclosure, the first group 300_R that may collect nanorods of the same size may be located at each of the plurality of branch pipes. Accordingly, the chemical liquid supply apparatus may classify nanorods of a certain size at a high flow rate. Accordingly, the chemical liquid supply apparatus 10e according to the disclosure may efficiently classify nanorods of a certain size.

By installing the second group 300_C that may collect nanorods of different sizes at one branch pipe, nanorods of various sizes may be collected and released at once. The chemical liquid supply apparatus 10e according to the disclosure may classify nanorods other than the nanorods mounted on a display among the plurality of nanorods at once through a plurality of classifiers arranged in series. Therefore, it is possible to prevent nanorods outside an error range from being sprayed onto a substrate, and thus, a high-quality display may be obtained.

So far, the disclosure is described with reference to the embodiments illustrated in the drawings, but these are only examples, and those skilled in the art will understand that various modifications and equivalent other embodiments may be made therefrom. Therefore, the true technical protection scope of the disclosure should be determined by the technical idea of the appended claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A chemical liquid supply apparatus comprising:
a chemical liquid storage tank storing a chemical liquid including a plurality of nanorods;
a circulation pipe having both ends connected to the chemical liquid storage tank and including a first branch pipe and a second branch pipe;
a classifier located at the second branch pipe and including a classification chip and a power supply; and
a discharge pipe configured to discharge the chemical liquid to an outside of the circulation pipe,
wherein the classification chip collects and releases nanorods of a certain size among the plurality of nanorods,
the discharge pipe discharges the nanorods of the certain size to the outside before the nanorods of the certain size released by the classification chip are returned to the chemical liquid storage tank, and
the power supply supplies an alternating current to the classification chip.

2. The chemical liquid supply apparatus of claim 1,
wherein the classification chip includes a first electrode layer, an insulating layer, and a second electrode layer, and
the insulating layer is located between the first electrode layer and the second electrode layer.

3. The chemical liquid supply apparatus of claim 2,
wherein the insulating layer includes a plurality of first holes, and
the second electrode layer includes a plurality of second holes communicating with the first hole.

4. The chemical liquid supply apparatus of claim 3,
wherein a width of the first hole is reduced closer toward the first electrode layer, and
a width of the second hole is reduced closer toward the insulating layer.

5. The chemical liquid supply apparatus of claim 3,
wherein a width of the first hole is about 10 μm to about 800 μm, and
a sum of a thickness of the first hole and a thickness of the second hole is about 10 μm to about 1200 μm.

6. The chemical liquid supply apparatus of claim 3, wherein a distance between the plurality of first holes is about 10 μm to about 100 μm.

7. The chemical liquid supply apparatus of claim 1,
wherein one end of the circulation pipe is connected to a lower surface of the chemical liquid storage tank, and the other end of the circulation pipe is connected to an upper surface of the chemical liquid storage tank, and
the chemical liquid flows out of the chemical liquid storage tank at the one end of the circulation pipe and flows into the chemical liquid storage tank at the other end of the circulation pipe.

8. The chemical liquid supply apparatus of claim 1, further comprising:
a degassing device configured to remove air bubbles in the chemical liquid.

9. The chemical liquid supply apparatus of claim 1, further comprising:
a distribution measurer configured to measure a degree of distribution of the plurality of nanorods in the chemical liquid.

10. The chemical liquid supply apparatus of claim 1, wherein a flow rate of the chemical liquid flowing through the first branch pipe is greater than a flow rate of the chemical liquid flowing through the second branch pipe.

11. The chemical liquid supply apparatus of claim 1, wherein the chemical liquid storage tank includes a first chemical liquid storage tank and a second chemical liquid storage tank.

12. The chemical liquid supply apparatus of claim 1, further comprising:
a head configured to spray the chemical liquid onto a substrate;
a supply pipe and a return pipe, connecting the head and the chemical liquid storage tank to each other; and
a controller configured to control collection and release of the nanorods of the classifier.

13. The chemical liquid supply apparatus of claim 12,
wherein the controller controls the classifier to collect the nanorods of the certain size while the head is spraying the chemical liquid, and
controls the classifier to release the nanorods of the certain size through the discharge pipe while the head is not spraying the chemical liquid.

14. A chemical liquid supply apparatus comprising:
a chemical liquid storage tank storing a chemical liquid including a plurality of nanorods;
a circulation pipe having both ends connected to the chemical liquid storage tank and including a main flow pipe and a plurality of branch pipes;
a plurality of classifiers respectively located at the plurality of branch pipes and each including a classification chip and a power supply;
a plurality of discharge pipes configured to discharge the chemical liquid to an outside of the circulation pipe; and
a plurality of control valves respectively located at the plurality of branch pipes and respectively adjusting flow rates of the chemical liquid flowing through the plurality of branch pipes,
wherein the classification chip collects and releases nanorods of a certain size among the plurality of nanorods,
the plurality of discharge pipes discharge the nanorods of the certain size to the outside before the nanorods of the certain size released by the classification chip are returned to the chemical liquid storage tank, and
the power supply supplies an alternating current to the classification chip.

15. The chemical liquid supply apparatus of claim 14, wherein some of the plurality of classifiers are located in series at one of the plurality of branch pipes.

16. The chemical liquid supply apparatus of claim 15, wherein the plurality of classifiers located in series at the one branch pipe are configured to collect and release nanorods of different sizes.

17. The chemical liquid supply apparatus of claim 14, wherein some of the plurality of classifiers are located at different branch pipes of the plurality of branch pipes.

18. The chemical liquid supply apparatus of claim 17, wherein the plurality of classifiers located at the different branch pipes of the plurality of branch pipes collect and release nanorods of the same size.

19. The chemical liquid supply apparatus of claim 14,
wherein some of the plurality of classifiers that collect and release nanorods of the same size are located at the plurality of branch pipes that are different from each other, and
some of the plurality of classifiers that collect and release nanorods of different sizes are located at one of the plurality of branch pipes.

20. A chemical liquid supply apparatus comprising:
a chemical liquid storage tank storing a chemical liquid including a plurality of nanorods;
a circulation pipe having both ends connected to the chemical liquid storage tank and including a main flow pipe and a plurality of branch pipes;
a degassing device located at the circulation pipe and configured to remove air bubbles in the chemical liquid;
a distribution measurer located at the chemical liquid storage tank and configured to measure a degree of distribution of the plurality of nanorods in the chemical liquid;
a plurality of classifiers respectively located at the plurality of branch pipes and each including a classification chip and a power supply;
a plurality of discharge pipes configured to discharge the chemical liquid to an outside of the circulation pipe;
a plurality of control valves respectively located at the plurality of branch pipes and configured to adjust flow rates of the chemical liquid flowing through the plurality of branch pipes;
a head configured to spray the chemical liquid onto a substrate;
a supply pipe and a return pipe, connecting the head and the chemical liquid storage tank to each other; and
a controller configured to control collection and release of the nanorods of the classifier,
wherein the classification chip includes a first electrode layer, an insulting layer, and a second electrode layer and collects and releases nanorods of a certain size among the plurality of nanorods,
the plurality of discharge pipes discharge the nanorods of the certain size to the outside before the nanorods of the certain size released by the classification chip are returned to the chemical liquid storage tank,
the power supply supplies an alternating current to the classification chip, and
the controller controls the plurality of classifiers to collect the nanorods of the certain size while the head is spraying the chemical liquid and
controls the plurality of classifiers to release the nanorods through the plurality of discharge pipes while the head is not spraying the chemical liquid.
